(19) United States
(12) Patent Application Publication
(10) Pub. No.: US 2013/0099369 A1
(43) Pub. Date: Apr. 25, 2013

(54) Hermetic Surface Mount Packages for Diodes and Transistors

(71) Applicant: Semicoa Corporation, Costa Mesa, CA (US)

(72) Inventors: Dale S. Shimane, Tracy, CA (US); Perry A. Denning, Mission Viejo, CA (US)

(73) Assignee: SEMICOA CORPORATION, Costa Mesa, CA (US)

(21) Appl. No.: 13/655,680

(22) Filed: Oct. 19, 2012

Related U.S. Application Data
(60) Provisional application No. 61/549,097, filed on Oct. 19, 2011.

(51) Int. Cl. H01L 23/498; H01L 21/60

(52) U.S. Cl. 257/698; 438/119; 257/E23.06; 257/E21.514

(57) ABSTRACT

A discrete semiconductor package includes a discrete semiconductor device disposed upon a non-conductive substrate, with via-connected upper and lower conductive ports. By utilizing a plurality of vias to connect the ports within the non-conductive substrate, and by depositing metals directly upon the surface of the substrate, manufacturing of such semiconductor packages is cheaper and more effective.

### PRIORITY

This application claims priority to U.S. Provisional Application No. 61/549097, filed Oct. 19, 2011, which is incorporated herein by reference in its entirety.

### FIELD OF THE INVENTION

The field of the invention is the manufacture of semiconductor devices.

### BACKGROUND

It is known to produce semiconductor devices for engineering use. The discovery of substrates such as silicon and of new metals that can be layered on top of one another has paved the way for a plethora of new semiconductor devices. Discrete diodes and transistors are oftentimes used in high-stress environments, such as in outer space or underneath the ocean, and need to be properly sealed from the outside elements, lest the semiconductor be degraded from exterior elements.

U.S. Pat. No. 6,989,559 to Chen and U.S. Pat. No. 7,880,283 to Zhuang both teach discrete diodes that are hermetically sealed from the elements in order to prevent such issues. However, semiconductors created with the method taught by Zhang, however, have a relatively high resistivity, and thus require a great deal of power and produce a great deal of heat. In addition, such diodes can typically only be sealed with glass, which easily breaks in high-stress environments, ruining the hermetic seal.

These and all other extrinsic materials discussed herein are incorporated by reference in their entirety. Where a definition or use of a term in an incorporated reference is inconsistent or contrary to the definition of that term provided herein, the definition of that term provided herein applies and the definition of that term in the reference does not apply.

Unless the context dictates the contrary, all ranges set forth herein should be interpreted as being inclusive of their endpoints and open-ended ranges should be interpreted to include only commercially practical values. Similarly, all lists of values should be considered as inclusive of intermediate values unless the context indicates the contrary.

Thus, there is still a need for systems and methods to produce improved semiconductor devices.

### SUMMARY OF THE INVENTION

The inventive subject matter provides apparatus, systems and methods in which a discrete semiconductor package includes a discrete semiconductor device disposed upon a non-conductive substrate, with via-connected upper and lower conductive ports. In general, it is contemplated that by utilizing a plurality of vias to connect the ports within the non-conductive substrate, and by depositing metals directly upon the surface of the substrate, manufacturing of such semiconductor packages is cheaper and more effective.

As used herein, a “discrete semiconductor package” is a package whose substrate does not contain other components, as is the case with integrated circuits. Contemplated discrete semiconductor packages include discrete diodes and transistors which can be mounted upon printed circuit boards or other electronic assembly structures for the formation of more complex circuitry. As used herein, a “discrete semiconductor device” is a semiconductor that has been doped with both n-type and p-type charge carriers.

The non-conductive substrate can be any suitable shape, but is preferably rectangular. Non-conductive substrates preferably comprise a direct copper plated ceramic, wherein the ceramic is selected from the group consisting of aluminum oxide and aluminum nitride

The first port can likewise comprise any suitable material, including for example, electrolytic copper. In one set of embodiments the first port is plated or otherwise surface treated with at least one of nickel, gold or silver, including for example surface-treatment with a layering selected from the group consisting of: (a) electrolytic Cu/Ni/Au, (b) electrolytic Cu/Ni/Ag, (c) electrolytic Cu/electroless Ag, (d) electrolytic Cu/electroless Ni/Au, and (e) electrolytic Cu/electroless Ni/Pd/Au. The port is coupled can be advantageously coupled to a lower side of a plurality of vias within the non-conductive substrate, and the discrete diode device can be advantageously coupled to an upper side of a plurality of vias within the non-conductive substrate. Axial leads preferably extend from the first and second ports, respectively.

Preferred devices have at least 4 vias. The discrete diode device can be coupled to the upper side of at least one of the vias in any suitable manner, including soldering, using a conductive adhesive, and one or more wires. Vias are preferably filled with silver, copper, gold, aluminum, or other conductive material.

A lid can advantageously be used to hermetically seal an upper side of the non-conductive substrate. Contemplated lids include those that are plated with at least one of nickel, gold and silver. In some embodiments the lid can be soldered to a perimeter of the upper side of the substrate, preferably using a first solder having a higher melting point than a second solder used to couple the discrete diode device to the upper side of the first via.

Contemplate methods of manufacturing a discrete semiconductor package according to the teachings herein include the steps of: (1) manufacturing a non-conductive substrate having a first upper port conductively coupled to a first lower port and a second upper port conductively coupled to a second lower port; and (2) conductively coupling a discrete semiconductor to the first upper port and the second upper port, wherein the discrete semiconductor is selected from a discrete diode device and a discrete transistor device. In some embodiments the vias can be laser-drilled into the non-conductive substrate. The leads can be coupled to the ports as described above.

Also contemplated are methods of converting a discrete surface-mount semiconductor package into an axial-mount semiconductor package, comprising the steps of conductively coupling first and second axial leads to first and second ports, respectively of a surface-mount semiconductor package. The axial leads preferably comprise (a) a flat conductive surface having a surface area substantially the same as a surface area of the first port, and (b) an axial pin. The leads can be coupled to the ports as described above.

In some embodiments the first and second axial leads, and optionally third and fourth axial leads, can be stamped from a metal plate. Stamping can be done to preserve a frame along a perimeter of the metal plate, and the axial leads can be separated from the frame after the steps of conductively coupling the first and second axial leads, respectively.

Various objects, features, aspects and advantages of the inventive subject matter will become more apparent from the following detailed description of preferred embodiments, along with the accompanying drawing figures in which like numerals represent like components.

### BRIEF DESCRIPTION OF THE DRAWING

FIGS. 1-4 are schematics depicting an exemplary diode package of the present invention.

FIG. 5-7 depicts images of an exemplary diode package.

FIGS. 8-11 depict a discrete MOSFET transistor package according to the teachings herein.

FIGS. 12-15 are schematics of an exemplary axial lead frame.

FIGS. 16-18 are schematics of a diode package conductively coupled to axial leads.

FIGS. 19-20 depict steps in coupling diode packages to the upper and lower connectors, with the outside wire frame eventually being cut or broken off.

FIG. 21-22 depict a diode package of FIGS. 19-20.

### DETAILED DESCRIPTION OF THE DRAWINGS

The following discussion provides example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

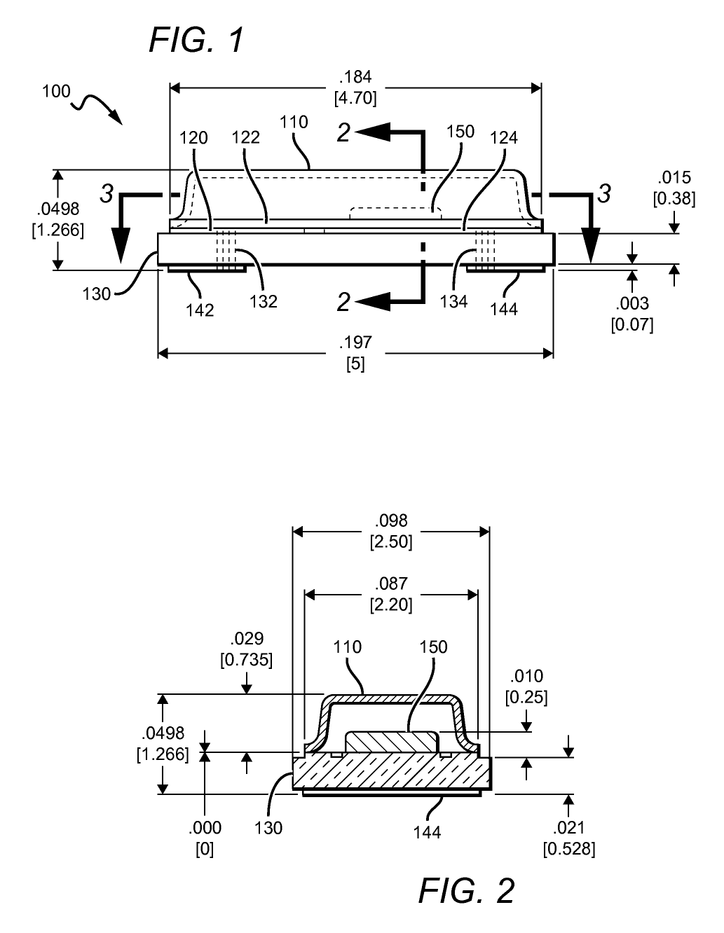

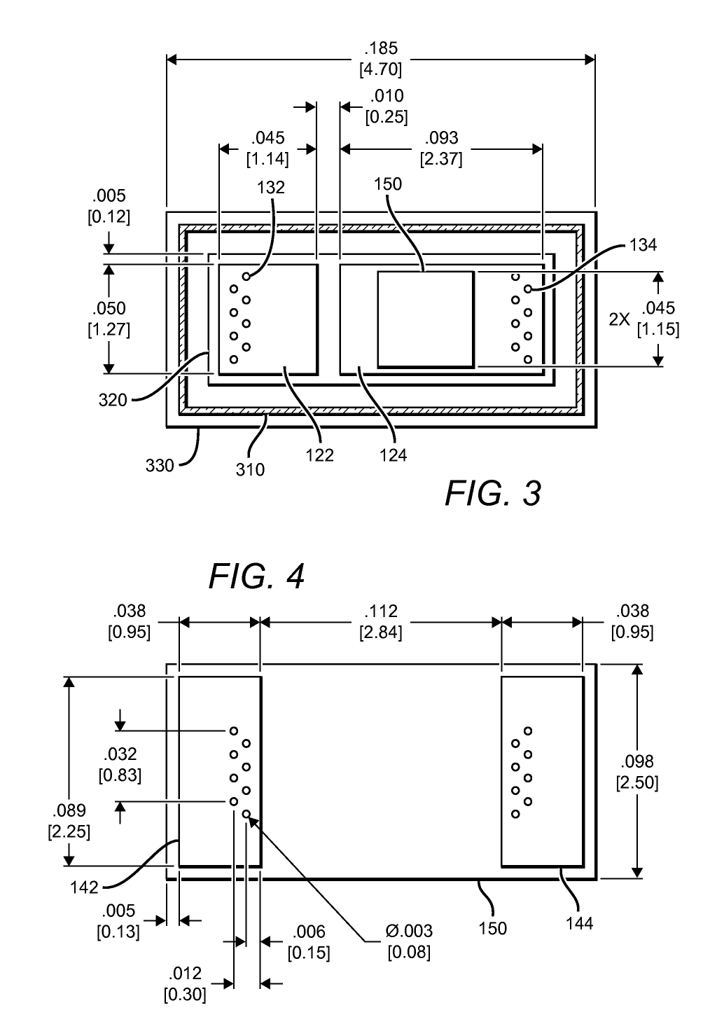

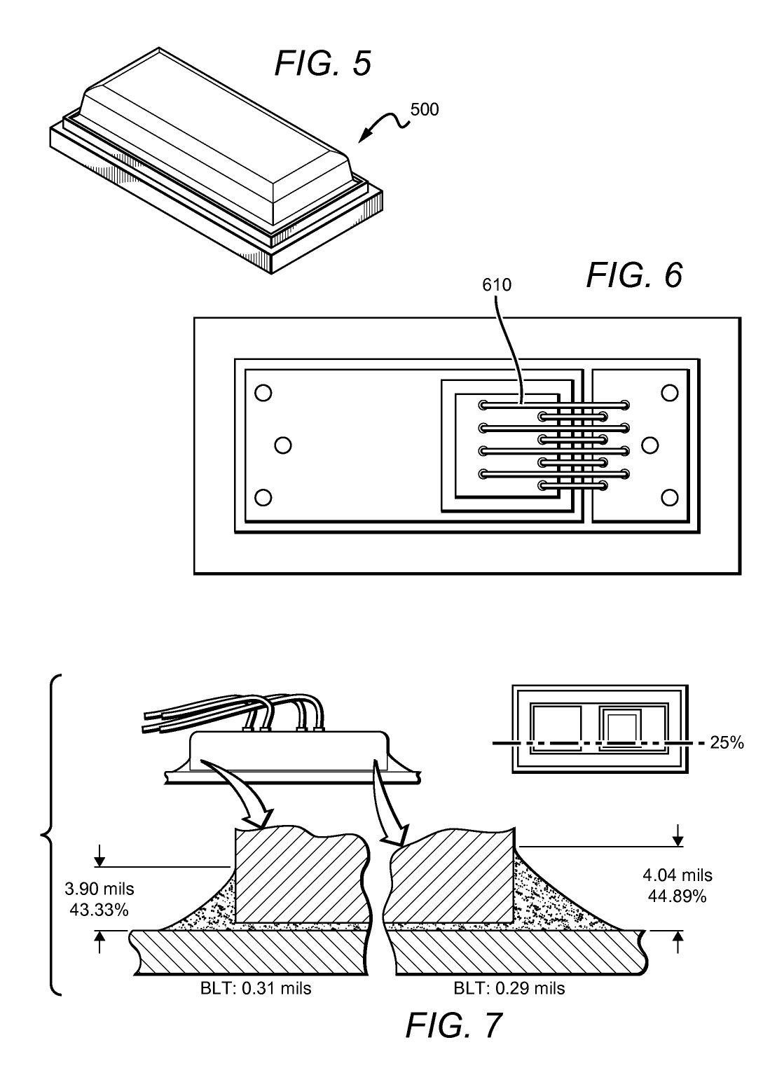

FIGS. 1-4 show an exemplary diode package 100 of the present invention, with measurements in inches [mm] format. Exemplary diode package 100 generally has a hermetically sealed lid 110, upper metal rim 120, upper anode connector 122, upper cathode connector 124, non-conductive substrate 130, lower anode connector 142, lower cathode connector 144, vias 132 and 134, and discrete diode device 150. As shown, discrete diode device 150 is a semiconductor with an upper layer having a p-type doping and a lower layer of an n-type doping. The upper p-type layer of discrete diode device 150 is coupled to upper anode connector 122 through a plurality of wires (not shown). Upper anode connector is coupled to lower anode connector 142 through the plurality of vias 132, while upper cathode connector is coupled to lower cathode connector 144 through the plurality of vias 134. This allows a current to flow from lower anode connector 142, through vias 132, to upper anode connector 122, to discrete diode device 150, to upper cathode connector 124, through vias 134, and finally to lower cathode connector 144. Wires 610, shown in FIG. 6 and FIG. 7 are preferably used to couple upper anode connector 122 with the upper p-type layer of discrete diode device 150, although the conductive coupling can be performed using other known methods, such as clip bonds, without departing from the scope of the current invention. Exemplary wires can be any conductive material, but are preferably made of aluminum, gold, or copper with various dopings (such as Si) to improve mechanical properties. The final exemplary diode package 500 is shown in the perspective FIG. 5.

Construction of diode package 100 is preferably performed by first starting with a plate of non-conductive substrate 130, preferably made from a type of ceramic (an electrical insulator), preferably aluminum oxide (Al₂O₃) or aluminum nitride (AlN), although any suitable non-conductive material can be used. Non-conductive substrate 130 is preferably sized and disposed to be a rectangular plane for ease of installation within existing systems, but can be shaped in any other manner without departing from the scope of the invention, such as being circularly shaped, square shaped, ovoid shaped, cylindrically shaped, trapezoidally shaped, or irregularly shaped. Once vias 132 and 134 are drilled, burned, or otherwise formed within the substrate, a metal can then be distributed along the surfaces of the substrate to form a physical structure for the formation of a discrete active semiconductor device. Preferably such metal is cohesively bonded to the non-conductive substrate using a sputtering technique, such as the technique disclosed in U.S. Pat. No. 6,800,211, which is incorporated herein by reference. However, such metal can be adhesively bonded to the non-conductive substrate using other known techniques, such as DPC/DBC (Direct Plated Copper/Direct Bonded Copper) techniques.

While eight vias are shown in the drawings as formed for each inter-substrate connection, more or less vias can be formed within the substrate depending upon needs, such as four, six, eight, ten, sixteen, twenty, or even at least thirty vias per connection port, in order to meet electrical current or thermal requirements for the package. While multiple vias are preferably used to couple upper and lower connectors through the non-conductive substrate in order to lower resistivity, a single large via or slug can be used without departing from the scope of the invention. Generally, after sputtering, the vias are substantially filled with a conductive material, such as silver, copper, gold, or aluminum, to conductively couple the upper and lower portions of the non-conductive substrate, and a mask is applied for etching away excess sputtered metal. As used herein, a via that is “substantially filled” is a via that has less than 5% void or air within its channel. The mask preferably has channels 310 and 320 on the upper side of diode package 100 that help to conductively isolate the connectors from the outer perimeter 330. These channels allow lid 110 to be soldered or otherwise coupled attached directly to the perimeter 330 without accidentally closing the circuit, should lid 110 be made of a conductive material.

Upper and lower anode and cathode connector ports 122, 124, 142, and 144 are generally made from a conductive material to serve as conductive connectors between the top surface and bottom surface of non-conductive substrate 130. The connector ports are preferably formed from an electrolytic copper, but can be made of any electrolytic or electroless material without departing from the scope of the invention, for example nickel or gold. Once the layer of conductive material is laid on the substrate, the connector ports can be plated with other materials using any suitable technique, such as chemical or electrochemical plating. For example, a layer of electrolytic copper can comprise the vias and the lower-most material for the connector ports, and a layer of nickel and then gold can then be plated on top of the connector ports, or a layer of nickel and then silver, a layer of electroless silver or nickel, a layer of electroless nickel and then a layer of gold, or a layer of electroless nickel, palladium, and then gold, and so on and so forth in any layering combination. Such plating can be used to improve connectivity as well as prevent corrosion of otherwise sensitive copper parts.

Once the vias and upper and lower connectors are bonded/etched/deposited in the substrate, discrete diode device 150 can then be conductively coupled to either of the upper connector ports using solder, epoxy, clip bonding, or some other attachment mechanism as shown in FIG. 7, and wires can be attached to couple the upper side of the diode to the opposing upper connector, completing the circuit. Preferably, a solder perform is used to couple the diode to the upper connector, such as a eutectic alloy line (AuSi) or a high lead (i.e. 92.5% Pb, 5% Sn, 2.5 Ag) solder. Alternatively, an organic glue is used, such as a silver-filled epoxy or cyanate ester. The upper side of the diode can then be hermetically sealed by soldering or gluing the lid to the perimeter of the upper side of the substrate, or can be left exposed if hermetic sealing is not necessary. The lid can be made from a conductive material and be plated with nickel and gold so as to serve as a ground for packages that need such. Preferably, the lid is coupled to the substrate with a solder that is of a higher melting point than solder used to couple the diode to the upper connector. As shown in the drawings, the diode is preferably sized and dimensioned to fit into any standard drop-in diode 4.7 mm×1.27 mm setting to replace current, hermetically sealed diodes. This creates a very thin, cheap, low-resistive diode package that can replace current diodes easily and efficiently.

Since the diode package 100 flows through a plurality of wires and a plurality of vias, the package has a much lower resistivity than a diode package with a single via, or a thick bar of conductive material, such as a metal slug, between the lower surface and the upper surface of the non-conductive substrate 130. By using such vias, the cost of producing the diode is much cheaper since the substrate and slugs do not need to be manufactured separately and put together, and since less copper is being used to create the connections.

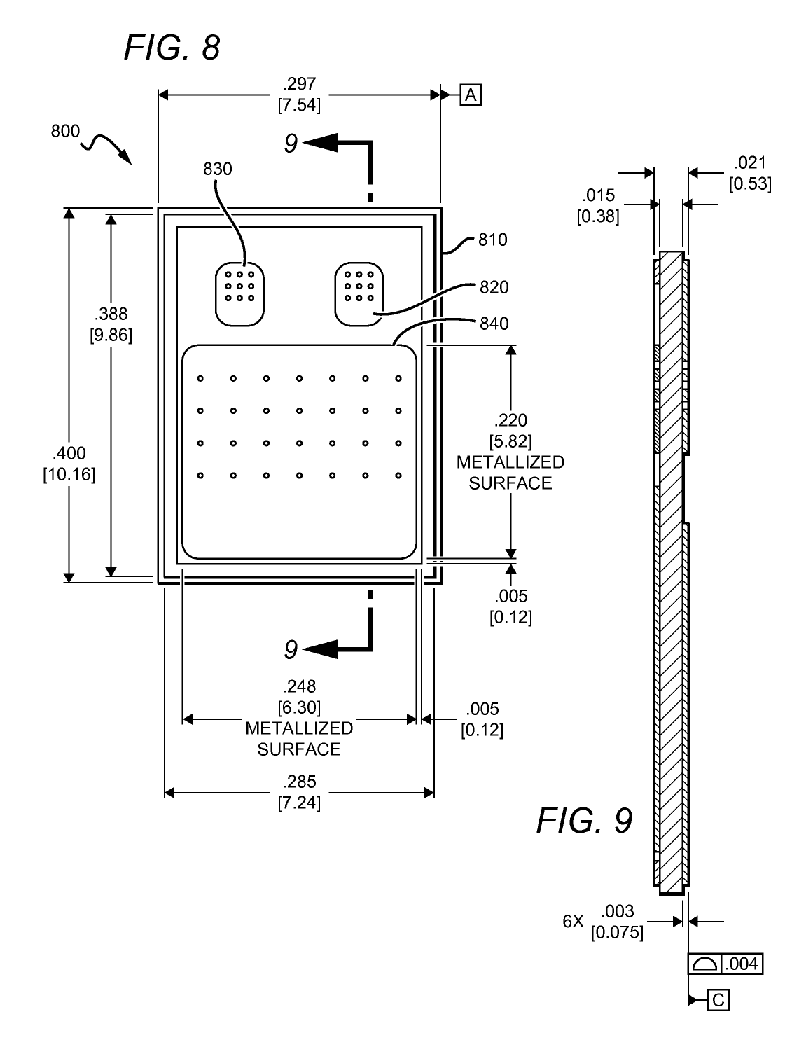

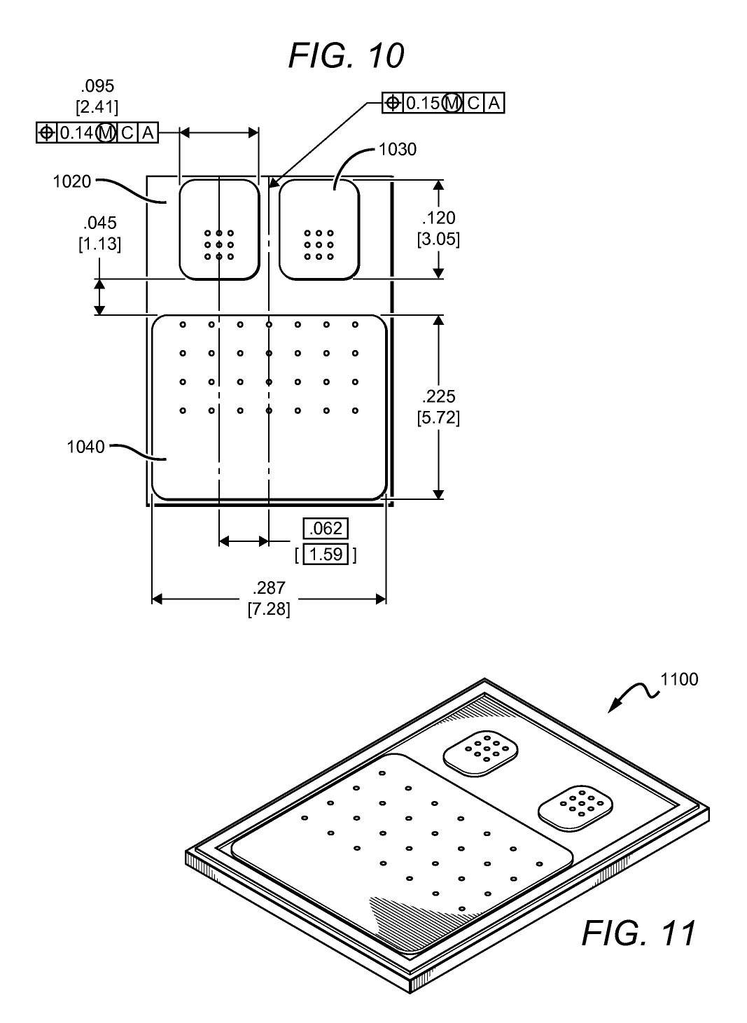

The same technique to create a diode can be used to create a discrete MOSFET transistor package 800, as shown in FIGS. 8-11, with upper source connector 830, lower source connector 1030, upper drain connector 820, lower drain connector 820, upper gate connector 840, and lower gate connector 1040. The discrete MOSFET transistor device itself is not shown in the drawings, but a person of ordinary skill in the art with knowledge of the diode package above can similarly attach a discrete MOSFET transistor device to the upper gate connector 840, couple wires from the source and drain portions of the discrete MOSFET transistor device to the upper drain and source connectors, and hermetically seal a lid to the perimeter 810 of the transistor package. Such a hermetically sealed transistor package would also be cheaper to manufacture, and would have less resistivity than the current hermetically sealed packages available today.

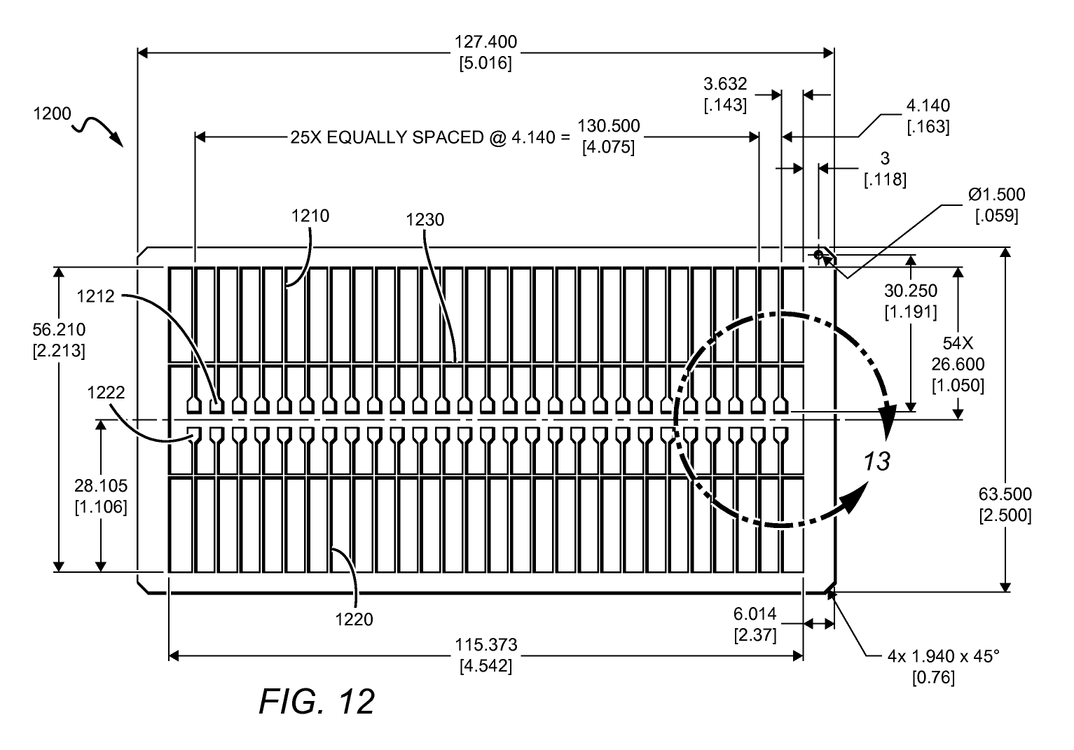

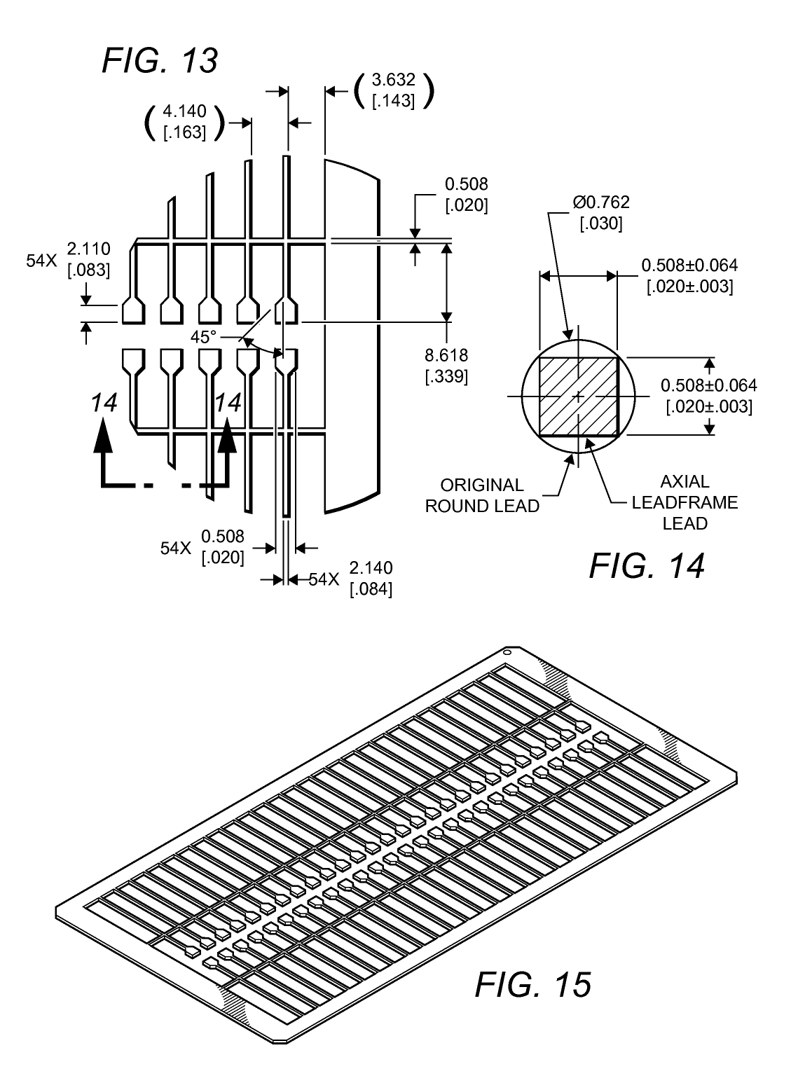

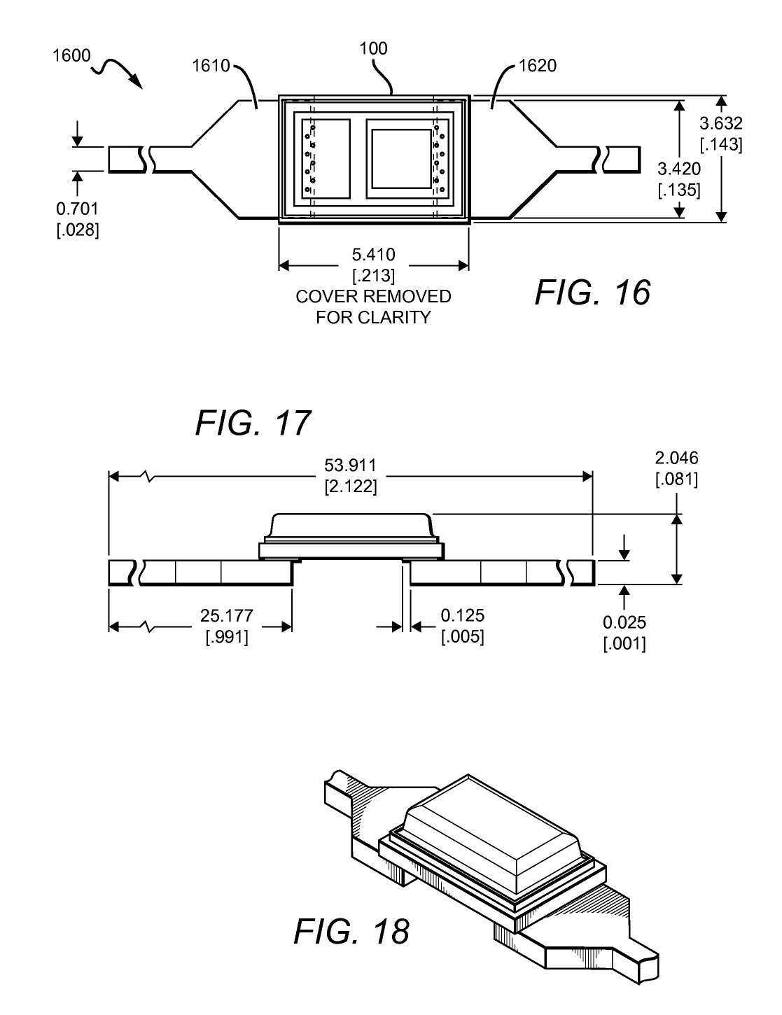

While diode package 100 can be dropped-in and soldered directly to a board or circuit, in an alternative embodiment, diode package 100 can be conductively coupled to axial leads 1610 and 1620 as shown in FIGS. 16-18 so that the transistor can be used in a standard breadboard/protoboard for testing purposes. An exemplary axial lead frame is disclosed in FIGS. 12-15, with upper leads 1210, lower leads 1220, upper lead connectors 1212, and lower lead connectors 1222. The units for this drawing are shown as mm [inches]. The conductive frame can be made in any suitable manner, such as etched upon a substrate and pulled off, but is preferably stamped from a single rectangular sheet of metal. One or more support bars 1230 can be left onto the frame in order to prevent the upper and lower axial leads from “sagging” after the frame has been stamped.

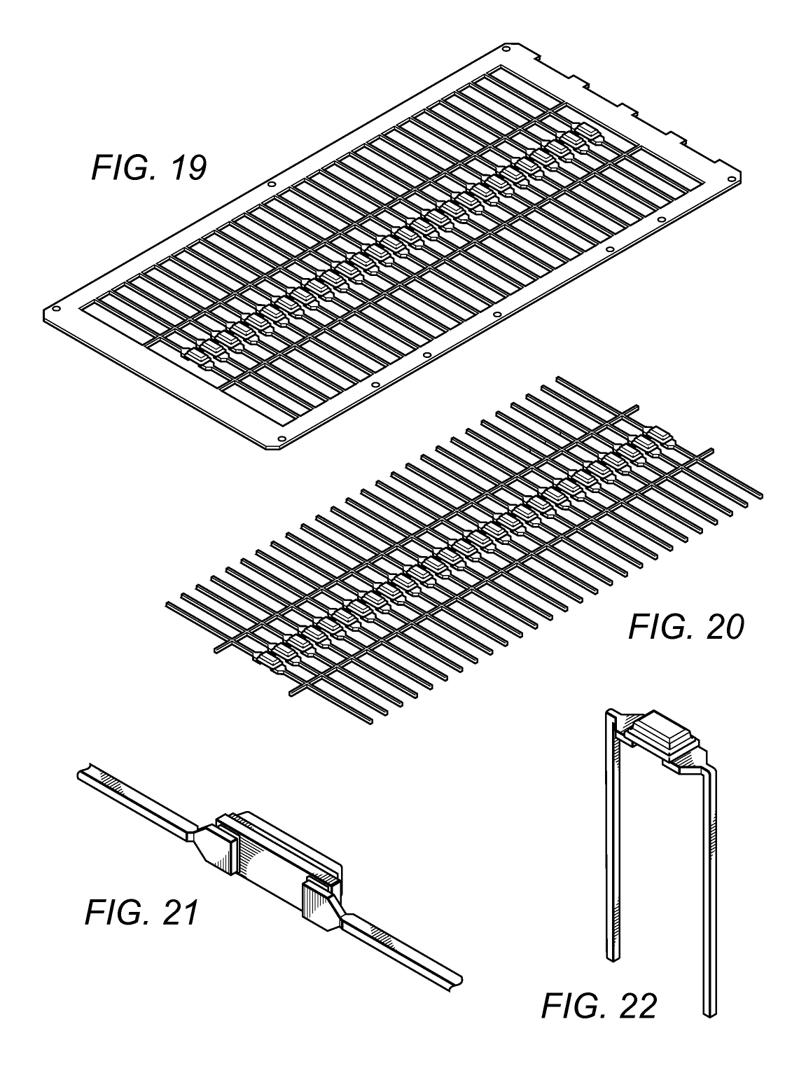

As shown in the figures, if axial frame 1200 is stamped, the ends of the axial leads will be square or rectangular, as shown in FIG. 14. As such, ensuring that the width of the axial lead is within a few degrees of tolerance from 0.5.08 mm, to ensure that the corners of the axial lead would properly electrically couple with a protoboard hole. The axial lead frame can be made from any suitable conductive material, for example copper, nickel, or aluminum. Once the axial frame is formed, constructed diode packages can be easily coupled to the upper and lower connectors as shown in FIG. 19, and the outside wire frame can be cut or broken off as shown in FIG. 20 and provided to a bulk purchaser as-is. A user can then break or cut off each diode as needed, and bend the leads for use in a protoboard as shown in FIGS. 21-22.

Various objects, features, aspects and advantages of the inventive subject matter will become more apparent from the detailed description of preferred embodiments, along with the accompanying drawing figures in which like numerals represent like components, and the appendix attached to this specification.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A discrete diode package, comprising:
a non-conductive substrate having a first via and a second via;
a first conductive port conductively coupled to a lower side of the first via;
a second conductive port conductively coupled to a lower side of the second via; and
a discrete diode device conductively coupled to an upper side of the first via and an upper side of the second via, wherein the first via conductively couples the first conductive port to the discrete diode device and the second via conductively couples the second conductive port to the discrete diode device.

2. The discrete diode package of claim 1, wherein the non-conductive substrate is rectangular.

3. The discrete diode package of claim 1, wherein the non-conductive substrate comprises a direct copper plated ceramic.

4. The discrete diode package of claim 3, wherein the ceramic is selected from the group consisting of aluminum oxide and aluminum nitride

5. The discrete diode package of claim 1, wherein the first port comprises electrolytic copper.

6. The discrete diode package of claim 1, wherein the first port is plated with a material selected from the group consisting of nickel and gold.

7. The discrete diode package of claim 1, wherein the first port is surface-treated with a layering selected from the group consisting of: (a) electrolytic Cu/Ni/Au, (b) electrolytic Cu/Ni/Ag, (c) electrolytic Cu/electroless Ag, (d) electrolytic Cu/electroless Ni/Au, and (e) electrolytic Cu/electroless Ni/Pd/Au.

8. The discrete diode package of claim 1, wherein the first conductive port is coupled to a lower side of a plurality of vias within the non-conductive substrate and wherein the discrete diode device is coupled to an upper side of a plurality of vias within the non-conductive substrate.

9. The discrete diode package of claim 8, wherein the plurality of vias comprises 4 vias.

10. The discrete diode package of claim 1, wherein the discrete diode device is soldered to the upper side of the first via.

11. The discrete diode package of claim 1, wherein the discrete diode device is coupled to the upper side of the first via using a conductive adhesive.

12. The discrete diode package of claim 10, wherein the discrete diode device is conductively coupled to the upper side of the second via with a wire.

13. The discrete diode package of claim 10, wherein the discrete diode device is conductively coupled to the upper side of the second via with a plurality of wires.

14. The discrete diode package of claim 1, further comprising a lid that hermetically seals an upper side of the non-conductive substrate.

15. The discrete diode package of claim 14, wherein the lid is plated with a material selected from the group selected from nickel and gold.

16. The discrete diode package of claim 14, wherein the lid is soldered to a perimeter of the upper side of the substrate.

17. The discrete diode package of claim 14, wherein the lid is soldered to the substrate using a first solder having a higher melting point than a second solder used to couple the discrete diode device to the upper side of the first via.

18. The discrete diode package of claim 1, wherein the first via is substantially filled with a conductive material.

19. The discrete diode package of claim 18, wherein the conductive material is selected from the group consisting of silver, copper, gold, and aluminum.

20. The discrete diode package of claim 1, further comprising coupling a first axial lead to the first port and a second axial lead to the second port.

21. A discrete transistor package, comprising:
a non-conductive substrate having a first via, a second via, and a third via;
a first, a second, and a third conductive port conductively coupled to a lower side of the first via, a lower side of the second via, and a lower side of the third via, respectively; and
a discrete transistor device conductively coupled to an upper side of the first via, an upper side of the second via, and an upper side of the third via, wherein the first via conductively couples the first conductive port to the discrete transistor device, the second via conductively couples the second conductive port to the discrete transistor device, and the third via conductively couples the third conductive port to the discrete transistor device.

22. The discrete transistor package of claim 21, wherein the non-conductive substrate is rectangular.

23. The discrete transistor package of claim 21, wherein the non-conductive substrate comprises a direct copper plated ceramic.

24. The discrete diode package of claim 23, wherein the ceramic is selected from the group consisting of aluminum oxide and aluminum nitride.

25. The discrete transistor package of claim 21, wherein the first port comprises electrolytic copper.

26. The discrete transistor package of claim 21, wherein the first port is plated with a material selected from the group consisting of nickel and gold.

27. The discrete transistor package of claim 21, wherein the first port is surface-treated with a layering selected from the group consisting of: (a) electrolytic Cu/Ni/Au, (b) electrolytic Cu/Ni/Ag, (c) electrolytic Cu/electroless Ag, (d) electrolytic Cu/electroless Ni/Au, and (e) electrolytic Cu/electroless Ni/Pd/Au.

28. The discrete transistor package of claim 21, wherein the first conductive port is coupled to a lower side of a plurality of vias within the non-conductive substrate and wherein the discrete transistor device is coupled to an upper side of a plurality of vias within the non-conductive substrate.

29. The discrete transistor package of claim 28, wherein the plurality of vias comprises 4 vias.

30. The discrete transistor package of claim 21, wherein the discrete transistor device is soldered to the upper side of the first via.

31. The discrete transistor package of claim 21, wherein the discrete transistor device is coupled to the upper side of the first via using a conductive adhesive.

32. The discrete transistor package of claim 30, wherein the discrete transistor device is conductively coupled to the upper side of the second via with a wire.

33. The discrete diode package of claim 10, wherein the discrete transistor device is conductively coupled to the upper side of the second via with a plurality of wires.

34. The discrete diode of claim 33, wherein the discrete transistor device is conductively coupled to the upper side of the third via with a plurality of wires.

35. The discrete transistor package of claim 21, further comprising a lid that hermetically seals an upper side of the non-conductive substrate.

36. The discrete transistor package of claim 35, wherein the lid is plated with a material selected from the group consisting of nickel and gold.

37. The discrete transistor package of claim 35, wherein the lid is soldered to a perimeter of the upper side of the substrate.

38. The discrete transistor package of claim 35, wherein the lid is soldered to the substrate using a first solder having a higher melting point than a second solder used to couple the discrete diode to the upper side of the first via.

39. The discrete transistor package of claim 21, wherein the first via is substantially filled with a conductive material.

40. The discrete transistor package of claim 39, wherein the conductive material is selected from the group consisting of silver, copper, gold, and aluminum.

41. The discrete transistor package of claim 21, further comprising coupling a first axial lead to the first port and a second axial lead to the second port.

42. A method of making a discrete semiconductor package, comprising:
manufacturing a non-conductive substrate having a first upper port conductively coupled to a first lower port and a second upper port conductively coupled to a second lower port; and
conductively coupling a discrete semiconductor to the first upper port and the second upper port, wherein the discrete semiconductor is selected from a discrete diode device and a discrete transistor device.

43. The method of claim 42, wherein the first upper port is conductively coupled to the first lower port through a via substantially filled with metal.

44. The method of claim 42, wherein the first upper port is conductively coupled to the first lower port through a plurality of vias substantially filled with metal.

45. The method of claim 42, wherein the step of manufacturing the non-conductive substrate comprises forming the non-conductive substrate into a rectangular package.

46. The method of claim 42, wherein the step of manufacturing the non-conductive substrate comprises laser-drilling vias into the non-conductive substrate;

47. The method of claim 46, wherein the step of manufacturing further comprises substantially filling the vias with metal.

48. The method of claim 42, wherein the step of conductively coupling the discrete semiconductor to the first upper port comprises soldering the discrete semiconductor to the first upper port.

49. The method of claim 42, wherein the step of conductively coupling the discrete semiconductor to the first upper port comprises gluing the discrete semiconductor to the first upper port using a conductive adhesive.

50. The method of claim 48, wherein the step of conductively coupling the discrete semiconductor to the second upper port comprises coupling a conductive wire to a surface of the discrete semiconductor and a surface of the second upper port.

51. The method of claim 48, wherein the step of conductively coupling the discrete semiconductor to the second upper port comprises coupling a plurality of conductive wires to a surface of the discrete semiconductor and a surface of the second upper port.

52. The method of claim 42, further comprising hermetically sealing a lid on an upper surface of the non-conductive substrate.

53. The method of claim 42, further comprising plating the first lower port with a material selected from the group consisting of nickel and gold.

54. The method of claim 42, further comprising surface-treating the first lower port with a layering selected from a group consisting of: (a) electrolytic Cu/Ni/Au, (b) electrolytic Cu/Ni/Ag, (c) electrolytic Cu/electroless Ag, (d) electrolytic Cu/electroless Ni/Au, and (e) electrolytic Cu/electroless Ni/Pd/Au.

55. A method of converting a discrete surface-mount semiconductor package into an axial-mount semiconductor package, comprising:
providing a substantially rectangular surface-mount semiconductor package having a first port and a second port;
conductively coupling a first axial lead to the first port; and
conductively coupling a second axial lead to the second port.

56. The method of claim 55, wherein the first axial lead comprises (a) a flat conductive surface having a surface area substantially the same as a surface area of the first port, and (b) an axial pin.

57. The method of claim 55, wherein the step of conductively coupling the first axial lead to the first port comprises soldering the first axial lead to the first port.

58. The method of claim 55, wherein the step of conductively coupling the first axial lead to the first port comprises gluing the first axial lead to the first port using a conductive adhesive.

59. The method of claim 55, further comprising stamping the first axial lead and the second axial lead from a metal plate.

60. The method of claim 59, wherein the step of stamping the first axial lead and the second axial lead comprises stamping a third axial lead and a fourth axial lead from the metal plate.

61. The method of claim 60, further comprising:
conductively coupling the third axial lead to a second surface-mount semiconductor package; and
conductively coupling the fourth axial lead to the second surface-mount semiconductor package.

62. The method of claim 59, wherein the step of stamping the first axial lead and the second axial lead comprises preserving a frame along a perimeter of the metal plate.

63. The method of claim 62, further comprising separating the first and second axial leads from the frame after the steps of conductively coupling the first and second axial leads, respectively.
